(19) United States
(12) Patent Application Publication
(10) Pub. No.: US 2023/0135341 A1
(43) Pub. Date: May 4, 2023

(54) SUPPORT BRACKETS WITH MULTIPLE ORIENTATIONS

(71) Applicant: HEWLETT-PACKARD DEVELOPMENT COMPANY, L.P., Spring, TX (US)

(72) Inventors: Wen Yen Tang, Taipei City (TW); Cheng-Han Tsai, Taipei City (TW); Chong-Wei Wu, Taipei City (TW); Wen Hua Ni, Taipei City (TW)

(21) Appl. No.: 17/512,893

(22) Filed: Oct. 28, 2021

(51) Int. Cl. H01R 33/97; H05K 7/12

(52) U.S. Cl. CPC H01R 33/97; H05K 7/12; H01R 12/73

(57) ABSTRACT

An example printed circuit board includes: a fixed portion disposed on the printed circuit board, the fixed portion defining a first end of a card slot to receive a card on the printed circuit board; a support bracket to be installed on the printed circuit board, the support bracket including a retaining portion to retain the card in the card slot, the retaining portion defining a second end of the card slot; and wherein the support bracket is orientable in one of: (i) a first orientation to define a first length of the card slot between the fixed portion and the retaining portion and (ii) a second orientation to define a second length of the card slot between the fixed portion and the retaining portion.

### BACKGROUND

Printed circuit boards may have card slots to receive cards enabling functionality, such as wireless capabilities, and the like. The printed circuit boards may therefore have components to receive and retain the cards.

### BRIEF DESCRIPTION OF THE DRAWINGS

FIG. 1A depicts an example printed circuit board with an example support bracket installed in a first orientation.

FIG. 1B depicts the printed circuit board of FIG. 1A with the example support bracket installed in a second orientation.

FIG. 2 depicts the example support bracket of FIG. 1A.

FIGS. 3A and 3B depict an exploded view of a printed circuit board and another example support bracket in a first and second orientation, respectively.

FIG. 4 depicts a side view of a printed circuit board with an example support bracket.

FIG. 5 depicts an example computing device with a printed circuit board with an example support bracket having multiple orientations.

### DETAILED DESCRIPTION

Sometimes, cards for printed circuit boards may have different sizes. For example, 4G and 5G wireless wide area network cards have different lengths. Accordingly, printed circuit boards with fixed components would have different versions of the board to each accept one of the 4G and 5G cards, creating difficulties in managing inventory. To accommodate this, some printed circuit boards may have different sized brackets which may be attached, however this still increases the number of components to be manufactured and tracked, and the brackets may be easily lost. Other solutions involve rotatable or slidable components to accommodate cards of different sizes. However, such solutions rely on the ability of the components to easily move between different positions, and hence may not retain the card in the proper position.

An example printed circuit board has a support bracket which can be installed in multiple orientations to change the length of the card slot for the printed circuit board. In particular, the support bracket has a retaining portion closer to one end of the support bracket so that when the support bracket is oriented in a first orientation, the retaining portion is closer to a fixed portion, such as a connector, a card slot or the like, on the printed circuit board, and when the support bracket is oriented in a second orientation, the retaining portion is further from the fixed portion of the printed circuit board. The retaining portion and the fixed portion define the card slot, and hence the card slot can receive cards of different lengths depending on the orientation of the support bracket. The support bracket and printed circuit board may also have corresponding alignment structures to restrict the movement of the support bracket from the selected orientation.

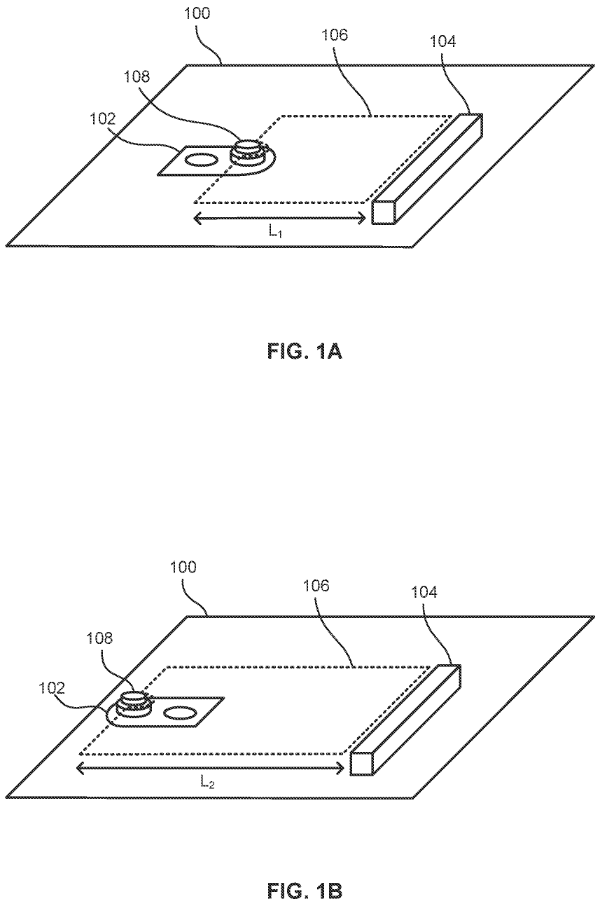

FIG. 1A depicts a printed circuit board (PCB) 100 with an example support bracket 102 installed in a first orientation. The PCB 100 includes the support bracket 102 and a fixed portion 104 disposed on the PCB 100.

Together, the support bracket 102 and the fixed portion 104 define a card slot 106 to receive a card on the PCB 100. For example, the card slot 106 may be to receive a wireless wide area network card (WWAN), to enable wireless communications at a computing device in which the PCB 100 is deployed. In particular, the fixed portion 104 defines a first end of the card slot 106 and the support bracket 102 defines a second end of the card slot 106.

The fixed portion 104 may be a card connector and include an opening, including pins, connectors, and the like, to form an electrical connection with the card received in the card slot 106.

The support bracket 102 includes a retaining portion 108 to retain the card in the card slot 106. For example, the retaining portion 108 may be generally cylindrical shaped to mate with a corresponding half-moon shaped recession on the card received in the card slot 106. The mating of the retaining portion 108 and the card may thus serve to retain the card in the card slot 106. Accordingly, the retaining portion 108 of the support bracket 102 defines the second end of the card slot 106.

The support bracket 102 may be installed on the PCB 100 in one of two orientations, as depicted in FIGS. 1A and 1B. In FIG. 1A, the support bracket 102 is oriented in a first orientation, with the retaining portion 108 closer to the fixed portion 104. Thus, the support bracket 102 defines a first length L₁ of the card slot 106, where L₁ is defined between the fixed portion 104 and the retaining portion 108. In FIG. 1B, the support bracket 102 is oriented in a second orientation, with the retaining portion 108 further from the fixed portion 104. Thus, the support bracket 102 defines a second length L₂ of the card slot 106, where L₂ is similarly defined between the fixed portion 104 and the retaining portion 108 and is longer than L₁.

As can be seen, in each orientation of the support bracket 102, the card slot 106 may be defined with different lengths, based on the distance of the retaining portion 108 from the fixed portion 104. Accordingly, the PCB 100 may be configured to have a card slot 106 which accepts cards of different lengths. For example, the if the card is a WWAN card, the support bracket 102 may be configured such that in the first orientation, the card slot 106 accepts a 4G WWAN card, having a length of 38 mm, and in the second orientation, the card slot 106 accepts a 5G WWAN card, having a length of 48 mm. In other examples, the card may be a storage drive, such as an M.2 storage drive, having different lengths for different lengths for different storage quantities. Further, both cards or drives may be accepted on the same PCB 100 without acquiring a new PCB when, for example, a user wants to upgrade from 4G wireless communications to 5G wireless communications, or from one storage drive to a higher capacity storage drive.

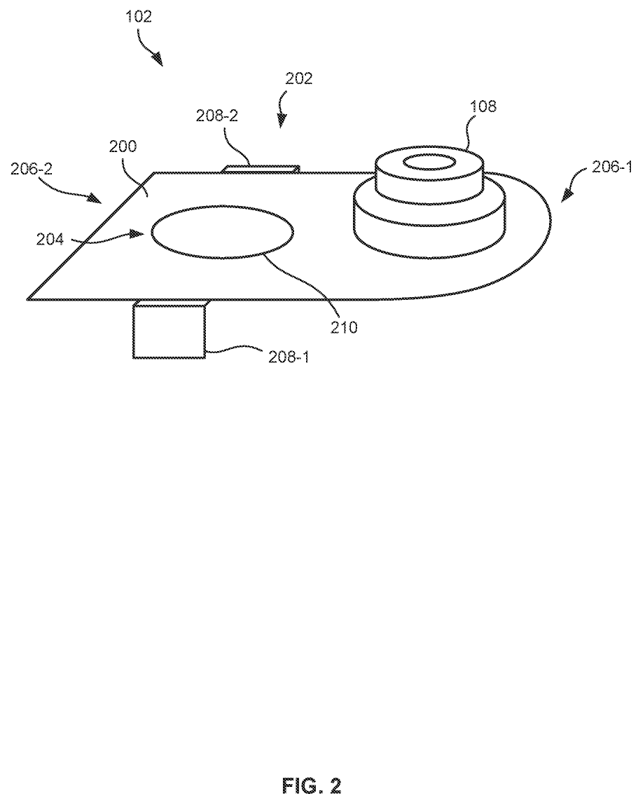

FIG. 2 depicts a close-up view of the example support bracket 102. The support bracket 102 includes a base 200, a bracket alignment structure 202 and an attachment structure 204 in addition to the retaining portion 108. In some examples, the support bracket 102 may be formed of a conductive material, such as a metal, to ground a card received in the card slot 106, while in other examples, the support bracket 102 may be formed of an insulating material, such as a plastic, a rubber, or the like, to avoid any interference with the circuitry on the PCB 100. The material of the support bracket 102 may be selected based on the suitable conductivity effects of the support bracket 102.

The base 200 has a first end 206-1 and a second end 206-2 and is generally to support the components of the support bracket 102. In particular, the retaining portion 108 is supported on the base at or proximate the first end 206-1 to allow the retaining portion 108 to have a varying position relative to the fixed portion 104 based on the orientation of the support bracket 102, as will be described in further detail below.

The bracket alignment structure 202 is at the second end 206-2 of the base 200 and cooperates with a board alignment structure (not shown) on the PCB 100, to together form an alignment structure to align the support bracket 102 in one of the first orientation and the second orientation. In the present example, the bracket alignment structure 202 includes guide pins 208-1 and 208-2 extending from the base 200 of the support bracket 102. In particular, the first guide pin 208-1 extends from a first side of the base 200 in a direction opposite the retaining portion 108, proximate the second end 206-1, and the second guide pin 208-2 extends from a second side of the base 200 in a direction opposite the retaining portion 108, proximate the second end 206-1. The guide pins 208-1, 208-2 are to be received in corresponding guide holes of the PCB 100 to align the support bracket 102 on the PCB 100.

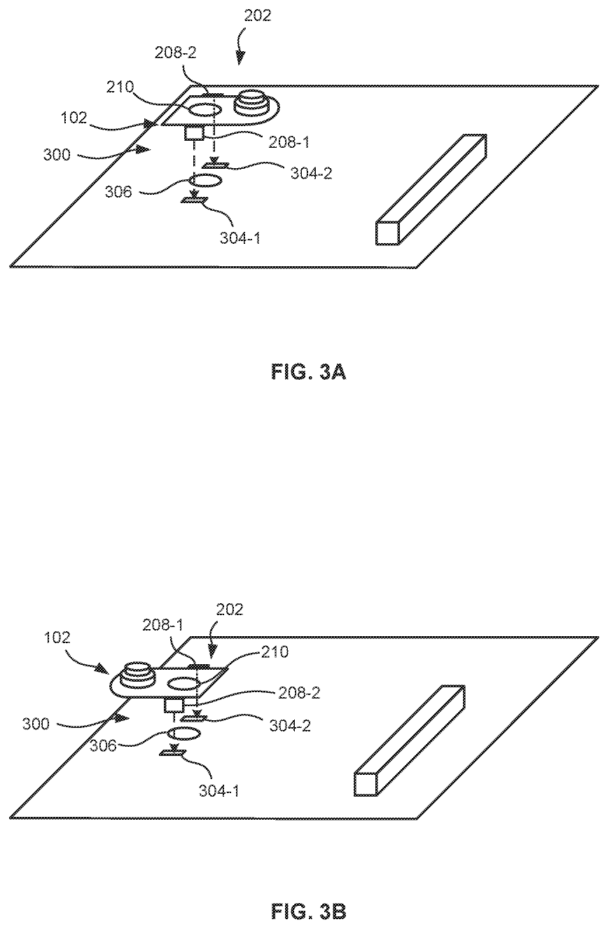

For example, FIGS. 3A and 3B depict another example support bracket 102 separated from the PCB 100 to show a board alignment structure 300 of the PCB 100. The board alignment structure 300 is generally to align the support bracket 102 on the PCB 100. In particular, the board alignment structure 300 aligns the support bracket 102 in the first orientation or the second orientation and maintains the support bracket 102 in the selected orientation. For example, the board alignment structure 300 may prevent the support bracket 102 from inadvertently being switched, rotated, or slid to a different orientation, for example during transport of the PCB 100 or when the computing device in which the PCB 100 is deployed is in use.

In the present example, the board alignment structure 300 includes guide holes 304-1 and 304-2 in the PCB 100. The guide holes 304-1 , 304-2 are to receive the guide pins 208-1, 208-2 to align the support bracket 102 on the PCB 100. More generally, the board alignment structure 300 and the bracket alignment structure 202 cooperate with one another to form an alignment structure to align the support bracket 102 on the PCB 100.

Further, the board alignment structure 300 and the bracket alignment structure 202 may be configured such that the same structures may be used to align the support bracket 102 in both the first orientation and the second orientation.

For example, the first guide hole 304-1 is to receive the first guide pin 208-2 and the second guide hole 304-2 is to receive the second guide pin 208-2 when the support bracket 102 is oriented in the first orientation, as can be seen in FIG. 3A. Further, the location of the guide pins 208-1, 208-2 at the sides of the support bracket 102 allow the guide pins 208-1, 208-2 and the guide holes 304-1, 304-2 to restrict the rotation of the support bracket 102 from the first orientation.

As can be seen in FIG. 3B, the guide holes 304-1, 304-2 and the guide pins 208-1, 208-2 may also be used to align the support bracket 102 in the second orientation. In particular, the first guide hole 304-1 is to receive the second guide pin 208-2 and the second hole 304-2 is to receive the first guide pin 208-1 when the support bracket 102 is oriented in the second orientation, opposite the first orientation. The guide pins 208-1, 208-2 and the guide holes 304-1, 304-2 may then restrict the rotation of the support bracket 102 from the second orientation.

As can be seen, the board alignment structure 300 is fixed relative to the fixed portion 104. Further, the spatial arrangement of the retaining portion 108 and the bracket alignment structure 202 at opposing ends 206-1 and 206-2 of the support bracket 102 allows the retaining portion 108 to be located in different positions relative to the fixed portion 104, thereby defining different lengths of the card slot 106. In particular, in the first orientation, the retaining portion 108 is positioned on a first side of the board alignment structure 300, proximate the fixed portion 104. In the second orientation, the retaining portion 108 is positioned on a second side of the board alignment structure 300, distal from the fixed portion 104.

Returning again to FIG. 2, the attachment structure 204 is generally to affix the support bracket 102 to the PCB 100. In the present example, the attachment structure 204 includes a screw hole 210 in the base 200 to receive a screw to affix the support bracket 102 to the PCB 100. The PCB 100 may have a corresponding screw hole 306 (depicted in FIGS. 3A and 3B). The screw holes 210, 306 may be arranged relative to the board alignment structure 300 to allow the same screw holes 210, 306 to be used when the support bracket 102 is oriented in the first orientation or the second orientation.

In some examples, the attachment structure 204 may additionally or alternately include double-sided tape to secure the support bracket 102 to the PCB 100. In particular, the double-sided tape may be applied to the surface of the support bracket 102 which contacts the PCB 100. The double-sided tape may additionally assist in maintaining proper alignment of the support bracket 102 in either the first orientation or the second orientation and restricting any additional rotation or sliding of the support bracket.

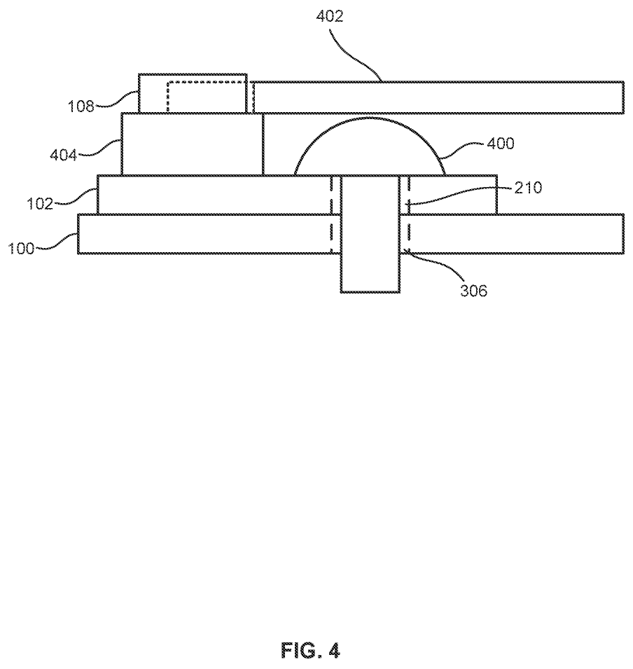

Referring to FIG. 4, a side view of the PCB 100 and the support bracket 102 oriented in the second orientation is depicted. In the second orientation, where the retaining portion 108 is positioned on the second side of the board alignment structure 302, the retaining portion 108 is further from the fixed portion 104 than the screw hole 210. Accordingly, when a screw 400 is received through the screw holes 210, 306, a card 402 received in the card slot lies over the screw 400 and the screw holes 210, 306.

The support bracket 102 may therefore further include a nut step 404 to elevate the retaining portion 108, such that the card 402 is elevated above the screw 400 when the support bracket 102 is aligned in the second orientation. That is, the card 402 rests on the nut step 404 when retained by the retaining portion 108, and the nut step 404 has a sufficient height to elevate the card 402 above the screw 400.

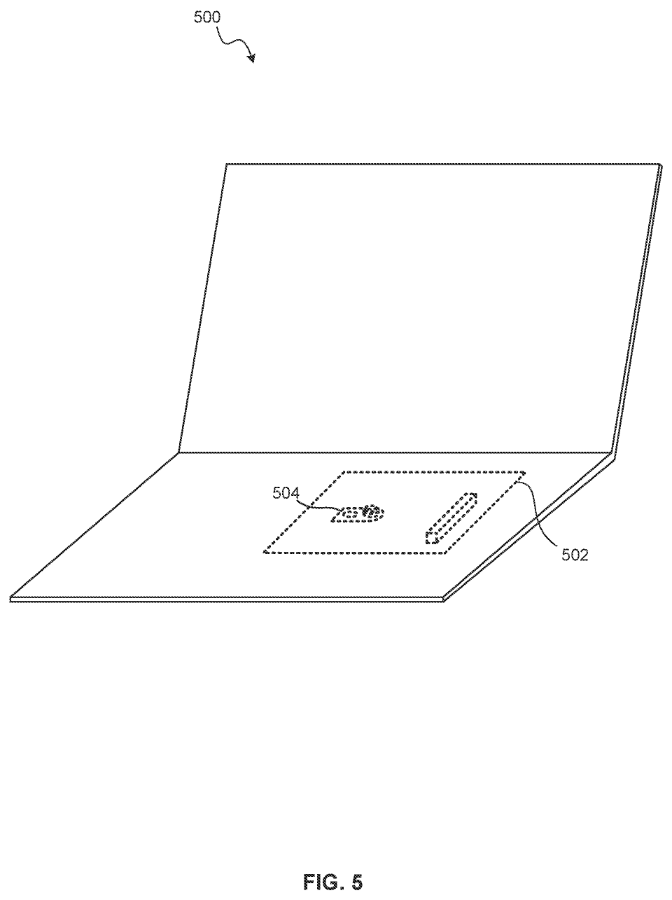

FIG. 5 depicts an example computing device 500 employing a PCB 502. The computing device 500 is depicted in the present example as a laptop computer, but may be any suitable computer device, including, but not limited to, desktop computers, tablets, printers, monitors, mobile devices, all-in-one devices, and the like.

The PCB 502 includes a card slot to receive a card on the PCB 502. The computing device 500 further includes a support bracket 504 to be installed on the PCB 502 to define the card slot. The support bracket 504 is orientable in a first orientation to define a first length of the card slot, or a second orientation opposite the first orientation to define a second length of the card slot. For example, the PCB 502 may be similar to the PCB 100, and the support bracket 504 may be similar to the support bracket 102.

The card slot may therefore receive a first card of a first length when the support bracket 504 is oriented in the first orientation. The card slot may alternately receive a second card of a second length when the support bracket is oriented in the second orientation. For example, the first card may be a first type of WWAN card, such as a 4G WWAN card, having a length of 38 mm. The second card may be a second type of WWAN card, such as a 5G WWAN card, having a length of 48 mm.

Thus, in order to switch between a 4G and a 5G WWAN card, users need not acquire a new computing device 500 or even a new PCB 502. Rather, the support bracket 504 may be changed from the first orientation to the second orientation (or vice versa) to allow the computing device 500 to accept and read the new card.

As described above, an example printed circuit board may have a support bracket which can be oriented in multiple orientations to define differing lengths of a card slot. The PCB may therefore use the same components (i.e., the board itself and the support bracket in one of the selected orientations) to receive cards of differing lengths. Further, the PCB and support bracket may have alignment and attachment structures to maintain the selected orientation of the support bracket, and to affix the support bracket to the PCB.

The scope of the claims should not be limited by the above examples, but should be given the broadest interpretation consistent with the description as a whole.

1. A printed circuit board comprising:
a fixed portion disposed on the printed circuit board, the fixed portion defining a first end of a card slot to receive a card on the printed circuit board;
a support bracket to be installed on the printed circuit board, the support bracket including a retaining portion to retain the card in the card slot, the retaining portion defining a second end of the card slot; and
wherein the support bracket is orientable in one of: (i) a first orientation to define a first length of the card slot between the fixed portion and the retaining portion and (ii) a second orientation to define a second length of the card slot between the fixed portion and the retaining portion.

2. The printed circuit board of claim 1, further comprising an alignment structure to align the support bracket in the first orientation or the second orientation when the support bracket is installed on the printed circuit board.

3. The printed circuit board of claim 2, wherein the alignment structure comprises:
a guide hole in the printed circuit board; and
a guide pin extending from the support bracket, the guide pin to be received in the guide hole in the printed circuit board to align the support bracket on the printed circuit board.

4. The printed circuit board of claim 1, further comprising an attachment structure to affix the support bracket to the printed circuit board.

5. The printed circuit board of claim 4, wherein the attachment structure comprises double-sided tape to affix the support bracket to the printed circuit board.

6. The printed circuit board of claim 4, wherein the attachment structure comprises:
screw holes in the support bracket and the printed circuit board; and
a screw extending through the screw holes to affix the support bracket to the printed circuit board.

7. The printed circuit board of claim 6, further comprising a nut step to elevate the retaining portion such that the card received on the printed circuit board is elevated above the screw when retained by the retaining portion.

8. A computing device comprising:
a printed circuit board including a card slot to receive a card on the printed circuit board; and
a support bracket to be installed on the printed circuit board to define the card slot, wherein the support bracket is orientable in (i) a first orientation to define a first length of the card slot and (ii) a second orientation opposite the first orientation to define a second length of the card slot.

9. The computing device of claim 8, wherein the card slot is to receive (i) a first card of the first length when the support bracket is oriented in the first orientation and (ii) a second card of the second length when the support bracket is oriented in the second orientation.

10. The computing device of claim 8, wherein the card slot is to receive (i) a first type of wireless wide area network card of the first length when the support bracket is oriented in the first orientation and (ii) a second type of wireless wide area network card of the second length when the support bracket is oriented in the second orientation.

11. A printed circuit board comprising:
a card connector disposed on the printed circuit board;
a board alignment structure;
a support bracket to be installed on the printed circuit board, the support bracket comprising:
a base having a first end and a second end;
a retaining portion supported on the base at the first end to define a card slot between the fixed portion and the retaining portion, the card slot to receive a card on the printed circuit board; and
a bracket alignment structure at the second end of the base to cooperate with the board alignment structure to align the support bracket on the printed circuit board in one of:
a first orientation, wherein the retaining portion is positioned on a first side of the board alignment structure, proximate the fixed portion; and
a second orientation, wherein the retaining portion is positioned on a second side of the board alignment structure, distal from the fixed portion.

12. The printed circuit board of claim 11, wherein the support bracket further comprises a screw hole to receive a screw to screw the support bracket to the printed circuit board.

13. The printed circuit board of claim 12, wherein the support bracket further comprises a nut step to elevate the retaining portion, such that the card is elevated above the screw when the support bracket is aligned in the second orientation.

14. The printed circuit board of claim 11, wherein:
the bracket alignment structure comprises a first guide pin extending from a first side of the base and a second guide pin extending from a second side of the base; and
the board alignment structure comprises a first hole and a second hole to receive the first and second guide pins.

15. The printed circuit board of claim 14, wherein:
the first hole is to receive the first guide pin and the second hole is to receive the second guide pin when the support bracket is oriented in the first orientation; and
the first hole is to receive the second guide pin and the second hole is to receive the first guide pin when the support bracket is oriented in the second orientation.
